(19) United States
(12) Patent Application Publication
(10) Pub. No.: US 2015/0116816 A1
(43) Pub. Date: Apr. 30, 2015

(54) Compact Single Frequency Laser

(71) Applicant: IPG Photonics Corporation, Oxford, MA (US)

(72) Inventors: Yuri Barannikov, Worcester, MA (US); Alexey Avdokhin, Brookline, MA (US)

(73) Assignee: IPG Photonics Corporation, Oxford, MA (US)

(21) Appl. No.: 14/068,877

(22) Filed: Oct. 31, 2013

(51) Int. Cl. H01S 5/068; H01S 5/024

(52) U.S. Cl. CPC H01S 5/068; H01S 5/02415
USPC 359/337.11; 359/344

(57) ABSTRACT

A single frequency laser system is configured with an elongated housing extending along a longitudinal axis and having opposite axially spaced upstream and downstream ends. The housing encloses a laser chip configured to emit a radiation which propagates along a light path and emitted through the downstream faucet thereof. One or more spaced frequency discriminators are mounted in the housing downstream from the chip so as to define an external resonant cavity with the upstream faucet of the of the laser chip. At least two or more separate thermoelectric coolers (“TEC”) are mounted in the housing to control the chip arid discriminators so that the system emits radiation at the desired frequency.

### BACKGROUND OF THE DISCLOSURE

1. Field of the Disclosure

The present disclosure relates to a light emitting device provided with a laser diode and delivery fiber.

2. Relevant Known Art

Laser diode sources are well known in the art and widely used for a variety of applications. Among numerous requirements applied to such sources, stabilized temperature, mechanical stability and compactness deserve close attention. The former two requirements are instrumental in a stabilized pump output which is of paramount importance in many laser systems because any deviation from the desired parameters causes a wavelength change. The latter is unacceptable in many configurations including single frequency laser systems which have an external resonant cavity. The compactness is a necessary condition required in the field,

Many known configurations of laser diode source address the wavelength locking issue—some successfully, others not. But the improvement comes at a price: laser diode sources tend to loose the desired compactness.

The U.S. Pat. No. 5,699,377 (“'377”) is just an example illustrating, certain structural aspects that still need to be addressed. The '377 patent discloses a narrow linewidth laser source having a laser chip with the configuration known as a standard Butterfly diode mount or package. The configuration as disclosed in the patent includes, among others, a laser diode and fiber clip mounted on respective separate thermoelectric coolers (“TEC”). The fiber chip and delivery fiber are located on respective opposite input and output sides of the laser diode. The compactness of the disclosed structure may not be optimal.

The laser diode module is a delicate device exposed to both mechanical and optical loads always present in the field. For example, in the context of fiber Bragg gratings (“FBG”), even a slight human intervention in the vicinity of the output fiber creates sufficient mechanical loads capable of destabilizing the desired wavelength. Optical loads are typically associated with, among others, backreflected radiation originated when the light propagates along an optical circuitry and impinges on a variety of formations, both desired and undesired, only to backreflect. The backreflected light again is amplified as it propagates towards the module and can seriously harm optical components. Furthermore, it is not unusual that due to various causes parasitic wavelengths are generated while the light propagates along the circuitry. When any light backreflected, it may and often does end up in the laser diode cavity which may detrimentally affect the stabilization of the desired wavelength.

A need therefore exists for a laser diode source characterized by a single, stabilized frequency, mechanical integrity and compactness.

### SUMMARY OF THE DISCLOSURE

This need is satisfied by the disclosed laser source. in particular, the source includes a housing enclosing a laser diode which is operative to generate a stabilized single frequency output, and a partially enclosed delivery fiber guiding the generated single frequency output outside the housing,

In accordance with one aspect, the delivery fiber is provided with a wavelength selective element also enclosed in the housing and defining an external resonant cavity between itself and the upstream faucet of the laser diode. The wavelength selective element may be selected from a FBG or volume Bragg grating. The laser diode and wavelength selective element are supported by respective spaced apart TECs. The use of separate TECs allows a flexible tuning of FBG. It also allows the wavelength selective element to be positioned in a close proximity to the diode which creates a reliable stress-resistant structure within the housing. Furthermore, closely positioned diode and selective element render the source to he compact.

A further aspect of the disclosed structure includes the enhanced optical and mechanical resistance to stresses originated outside the housing. This is realized by having an optical isolator located downstream from wavelength-selective element. The isolator may be configured as either a fiber isolator or a volume configuration. The isolator prevents backreflected light from reentering the resonant cavity. Otherwise, since the disclosed source may be part of a high power fiber laser system, the powerful amplified light reentering the cavity may compromise the wavelength stability. The isolator provides not only for the attenuation of the undesired backreflected optical frequencies, but also for dumping mechanical stresses occurred outside the housing of the device.

### BRIEF DESCRIPTION OF THE DRAWINGS

The above and other features and advantages will become more readily apparent from the following description accompanied by the drawings, in which:

FIG. 1 is a side elevational view of the disclosed laser source.

FIGS. 2A-2B are respective optical diagrammatic views of the disclosed illustrating a single-grating structure and a two-grating structure.

FIG. 3 is a diagrammatic view of a volume Bragg Grating (“VBG”)

### SPECIFIC DESCRIPTION

Reference will now be made in detail to the disclosed system. The drawings are in simplified form and are far from precise scale. The word “couple” and similar terms do not necessarily denote direct and immediate connections, but also include connections through intermediate elements or devices.

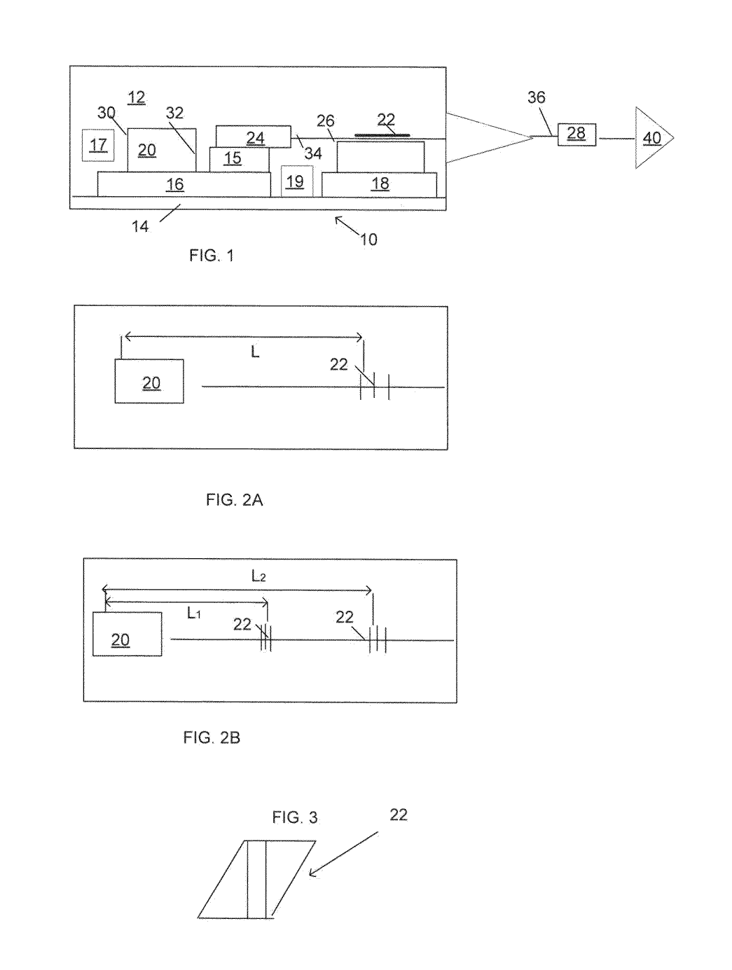

FIG. 1 illustrates the disclosed laser source 10 configured with a housing 12 which encloses a ceramic thermo-conducting plate 14 that provides for the mechanical rigidity of the source. Two separate TECs 16 and 18, respectively, are in thermo contact with a laser diode chip 20 of one of standard butterfly package types, and a wavelength selective element or frequency discriminator 22, The two separate TECs 16 and 18, respectively, are controlled by respective separate control circuits 17 and 19 which are typically located outside the housing, but here may also be mounted within housing 12. The use of multiple TECs, on one hand, provides for the stability of the desired central wavelength. On the other hand, the two-TEC structure improves the flexibility of the tuning process when a different central wavelength is needed.

The laser diode chip 20 is preferably configured as a powerful laser with an output of up to about several watts. The laser diode is configured with two opposite upstream and downstream faucets 30 and 32, respectively, defining an internal resonant cavity which generates a diode chip radiation through its downstream faucet 32 coated with an anti-reflection layer. The use of the powerful laser diode chip 20 is highly beneficial to the entire laser system for the following reasons. First, the fiber laser system may radiate a high power output without the necessity of using an optical amplifier. Second, the output light of the fiber laser system is highly coherent due to the inverse relationship between the power and linewidth expressed as

$$Δ v ∼ \frac{hv}{LLP out} ,$$

where Δv is a linewidth range, Pout—power output, L is the length of the resonator cavity,

The device 10 further includes a ferrule 24 mounted to a foundation 15 within the housing and configured to receive upstream end region 34 of fiber 26. The fiber 26 is preferably, but not necessarily, a polarization maintaining (PM) fiber which provides for the desired polarization extinction ratio (“PER”) of the output light.

The control circuit 17 driving laser diode chip 20 may have a current drive circuit and current sensor receiving the output of the drive circuit. The sensor is coupled to a temperature correction circuit operative to process the measured current and compare it to a reference value. The output from the temperature correction circuit is coupled to TEC 16 regulating chip 20 so as to generate the desired laser diode output.

Referring to FIGS. 2A and 2B, frequency discriminator 22 may be a fiber Bragg grating (“FBG”) mounted within the housing at a distance L from the upstream faucet of laser diode 20 so as to define the downstream end of the external cavity with upstream faucet 30 of laser diode 20. The external cavity, thus, refers to a portion of an optical cavity which is external to the internal laser cavity defined between faucets 30 and 32, respectively. The discriminator 22 is tunable, i.e., the element in which the particular wavelength of reflected output light may be adjusted to even farther narrow the laser chip radiation, as known to one of ordinary skills. Preferably, as shown, the range of tuning is achieved by applying thermally-induced stress generated by TEC 18. Other tuning techniques may include acoustically induced or mechanically stresses. The length L is selected so as to minimize the modehopping phenomenon and may be determined as

$$Δ f = \frac{c}{2 Lneff} ,$$

where c—is light speed, n_{eff}—effective index of refraction. To prevent the modehopping phenomenon, the modes should be spaced at a distance Δf of about 4 GHz from one another. Based on the above, the length L should not exceed about 2.5 sm.

FIG. 2B illustrates the configuration of laser light source 10 with two or more FBGs 22 providing even more stable generation of the desired frequency. To provide the single mode generation, the second length L₂ can be determined as follows:

$$L 2 s = L 1 + \frac{c}{neff Δ f max} ,$$

Δfmax>Δfgrating. For example, for distance L1=5 sm and Δfmax=8 GHz, L2 is 7.5 sm.

FIG. 3 illustrates an alternative configuration of frequency discriminator 22 structured as a volume holographic Bragg grating (“VBG”), which consists of a periodic phase or absorption perturbation throughout the entire volume of the element. The VBG 22 is a diffractive element operative to diffract only one given wavelength.

The device 10 further includes a pigtailed optical isolator 28 configured to minimize backreflected light propagation into the resonator and improve mechanical resistance of the inhouse structure to outside stress. if frequency discriminator 22 is configured as an FBG, device 10 is configured with a fiber optical isolator supporting fiber 26 outside the housing. The isolator 28 may be configured as a polarization maintaining fiber optic isolator, which achieves low insertion loss, high return loss and high isolation,

If frequency discriminator 22 is a VBG, isolator 28 can be configured as Faraday optical isolator. In this case, isolator 28 is installed within housing 12 upstream from the downstream end of fiber 26. The VHG has a configuration comprising a periodic or non periodic effective index of refraction and, for example, may have the fringe pattern stored in a holographic material. The fringe pattern comprises fringes of alternating indices of refraction, or a layered stack of material with alternating indices of refraction.

The fiber 26 is encapsulated in silicone which helps achieve the desired coupling of the fiber and discriminator 22 with the support, efficient dumping of mechanical stresses and reliable thermocontact for stabilizing the temperature of frequency discriminator 22. The use of silicone reduces the degassing effect so detrimental to the work of the chip.

It is possible to have the above-disclosed structure without ferrule 24. This configuration would allow FBG 22 to be mounted to the downstream faucet 34 of fiber 26 and have even a better mechanical stability.

The foregoing description and examples have been set forth merely to illustrate the disclosure and are not intended to be limiting. Accordingly, disclosure should be construed broadly to include all variation within the scope of the appended claims.

1. A laser system operative to emit a single frequency output, comprising:
a housing;
a laser chip mounted in the housing and configured to emit a laser radiation through a downstream output faucet of the laser chip along a light path;
a fiber mounted in the housing downstream from the chip and having an upstream end within the housing and a downstream end which extends beyond the housing;
a fiber Bragg grating (“FBG”) provided in the upstream end of the fiber to define an external resonant cavity with an upstream faucet of the of the laser chip;
a thermoelectric cooler (“TEC”) mounted in the housing and being in thermal communication with the laser chip so as to maintain the laser radiation;
a frequency regulator mounted in the housing and spaced from the TEC, the frequency regulator being coupled to the FBG and configured to prevent a shift of the single frequency output; and
a pigtailed isolator located downstream from the housing and coupled to the downstream end of the fiber to prevent backreflected propagation of light which is originated downstream from the optical isolator.

2. (canceled)

3. The system of claim 1, wherein the frequency regulator is selected from the group consisting of a TEC, acoustic source and mechanical source.

4. (canceled)

5. (canceled)

6. (canceled)

7. The system of claim 1 further comprising at least one additional FBG written in the fiber.

8. (canceled)

9. The system of claim 1, wherein the isolator has a polarization maintaining configuration or non-polarization maintaining configuration.

10. The system of claim 1 further comprising control circuits mounted in the housing and driving respective TEC and frequency regulator.

11. The system of claim further comprising drivers for respective TEC and frequency regulator, the drivers being mounted within the housing.
